(19) United States
(12) Patent Application Publication
(10) Pub. No.: US 2021/0405479 A1
(43) Pub. Date: Dec. 30, 2021

(54) DISPLAY PANEL MOTHERBOARD, MANUFACTURING METHOD THEREOF, AND DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventor: Renlu CHEN, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/616,981

(22) PCT Filed: Oct. 29, 2019
(86) PCT No.: PCT/CN2019/113857

§ 371 Date: Nov. 26, 2019

(30) Foreign Application Priority Data
Sep. 17, 2019 (CN) 201910874552.8

(51) Int. Cl. G02F 1/1362; G02F 1/1343

(52) U.S. Cl. CPC G02F 1/136254; G02F 1/1368; G02F 1/13439; G02F 1/136227

(57) ABSTRACT

The present invention provides a display panel motherboard, a manufacturing method thereof, and a display panel. The manufacturing method of the display panel motherboard includes: forming a first type through-hole in a central region of a substrate motherboard, forming a second type through-hole in an edge region of the substrate motherboard, and comparing a ratio of a contact resistance of the first type through-hole to a contact resistance of the second type through-hole to a default threshold value for designing a display panel motherboard that meets requirements.

### FIELD OF INVENTION

The present invention is related to the display field, and specifically to a display panel motherboard, a manufacturing method thereof, and a display panel.

### BACKGROUND OF INVENTION

Gate driver on array (GOA) technology directly fabricates gate driver integrated circuits (ICs) on array substrates.

With increase of image quality, a GOA circuit use a plurality of thin-film transistors (TFTs). Due to an accuracy problem of an etching process and different resistances of contact through-holes for connecting signals in a process, a turn-on voltage (V_{gh}) of the TFTs varies, which affects normal operation function and stability of an entire circuit.

Therefore, there is a need for a display panel to solve the above problems.

### SUMMARY OF INVENTION

The present invention provides a display panel motherboard, a manufacturing method thereof, and a display panel to solve a technical problem of poor stability of a current display panel circuit.

In order to solve the above technical problem, a technical solution provided by the present invention is as follows:

The present invention provides a manufacturing method of a display panel motherboard, including at least two display panels;

wherein the manufacturing method of the display panel motherboard includes steps of:

providing a substrate motherboard, forming a first type through-hole in a first region of the substrate motherboard, and forming a second type through-hole in a second region of the substrate motherboard;

obtaining a first contact resistance of the first type through-hole and a second contact resistance of the second type through-hole;

processing the first type through-hole and/or the second type through-hole if a ratio of the first contact resistance to the second contact resistance is greater than a default threshold value; and

forming a pixel electrode layer on the substrate motherboard to form an array substrate motherboard if the ratio of the first contact resistance to the second contact resistance is less than the default threshold value.

In the manufacturing method of the display panel motherboard of the present invention,

the substrate motherboard includes a substrate and a thin-film transistor layer disposed on the substrate; and

the step of obtaining the first contact resistance of the first type through-hole and the second contact resistance of the second type through-hole includes steps of:

obtaining a first angle between a slope of the first type through-hole and the substrate;

obtaining a second angle between a slope of the second type through-hole and the substrate;

obtaining the first contact resistance corresponding to the first angle according to the first angle; and

obtaining the second contact resistance corresponding to the second angle according to the second angle.

In the manufacturing method of the display panel motherboard of the present invention,

if the ratio of the first contact resistance to the second contact resistance is greater than the default threshold value, the first angle of the first type through-hole is decreased by an etching process.

if the ratio of the first contact resistance to the second contact resistance is greater than the default threshold value, the second angle of the second type through-hole is increased by an etching process.

In the manufacturing method of the display panel motherboard of the present invention,

if the ratio of the first contact resistance to the second contact resistance is greater than the default threshold value, the first angle of the first type through-hole is decreased and the second angle of the second type through-hole is increased by an etching process.

In the manufacturing method of the display panel motherboard of the present invention,

the first type through-hole is located on the at least two display panels near a central region of the substrate motherboard, and the second type through-hole is located on the at least two display panels near an edge region of the substrate motherboard; or

the first type through-hole is located between two neighboring display panels near the central region of the substrate motherboard, and the second type through-hole is located on a non-display panel near the edge region of the substrate motherboard; or

the first type through-hole is located on the at least two display panels near the central region of the substrate motherboard, and the second type through-hole is located on a non-display panel near the edge region of the substrate motherboard; or

the first type through-hole is located between two neighboring display panels near the central region of the substrate motherboard, and the second type through-hole is located on the at least two display panels near the edge region of the substrate motherboard.

The present invention further provides a display panel motherboard, including at least two display panels and an array substrate motherboard;

wherein the array substrate motherboard includes a first type through-hole located in a first region of the array substrate motherboard and a second type through-hole located in a second region of the array substrate motherboard; and

a ratio of a first contact resistance of the first type through-hole to a second contact resistance of the second type through-hole is less than a default threshold value.

In the array substrate motherboard of the present invention,

the first type through-hole is located on the at least two display panels near a central region of the array substrate motherboard, and the second type through-hole is located on the at least two display panels near an edge region of the array substrate motherboard; or

the first type through-hole is located between two neighboring display panels near the central region of the array substrate motherboard, and the second type through-hole is located on a non-display panel near the edge region of the array substrate motherboard; or

the first type through-hole is located on the at least two display panels near the central region of the array substrate motherboard, and the second type through-hole is located on a non-display panel near the edge region of the array substrate motherboard; or

the first type through-hole is located between two neighboring display panels near the central region of the array substrate motherboard, and the second type through-hole is located on the at least two display panels near the edge region of the array substrate motherboard.

In the array substrate motherboard of the present invention,

the first type through-hole includes a first through-hole and a second through-hole;

the first through-hole passes through a passivation layer and an interlayer insulating layer in the array substrate motherboard, and the second through-hole passes through a portion of the passivation layer;

the second type through-hole includes a third through-hole and a fourth through-hole; and

the third through-hole passes through the passivation layer and the interlayer insulating layer in the array substrate motherboard, and the fourth through-hole passes through the portion of the passivation layer.

The present invention further provides a display panel cutting from the above display panel motherboard, including a third type through-hole located in a central region of the display panel and a fourth type through-hole located in an edge region of the display panel;

wherein a ratio of a first contact resistance of the third type through-hole to a second contact resistance of the fourth type through-hole is less than the default threshold value.

In the display panel of the present invention,

the first region is a central region of the display panel; and

the second region is an edge region of the display panel.

Beneficial effects: the present invention adjusts an angle between contact through-holes in a central region and a substrate and an angle between contact through-holes in an edge region and the substrate of a display panel motherboard to improve uniformity of resistances of the contact through-holes of a display panel circuit and improve quality of a display panel.

### DESCRIPTION OF DRAWINGS

In order to describe technical solutions in the present invention clearly, drawings to be used in the description of embodiments will be described briefly below. Obviously, drawings described below are only for some embodiments of the present invention, and other drawings may be obtained by those skilled in the art based on these drawings without creative efforts.

FIG. 1 is a flowchart of a manufacturing method of a display panel motherboard of the present invention.

FIG. 2 is a plan schematic diagram of a substrate motherboard of the present invention.

FIG. 3 is a film structure diagram of a cross-sectional view A-A in FIG. 2.

FIG. 4 is a film structure diagram of a cross-sectional view B-B in FIG. 2.

FIG. 5 is a simulation circuit diagram of a display panel of the present invention.

FIG. 6 is a film structure diagram of an array substrate motherboard of the present invention.

FIG. 7 is a plan schematic diagram of the display panel motherboard of the present invention.

FIG. 8 is a film structure diagram of a cross-sectional view C-C in FIG. 7.

FIG. 9 is a film structure diagram of a cross-sectional view D-D in FIG. 7.

FIG. 10 is a plan schematic diagram of the display panel of the present invention.

### DETAILED DESCRIPTION OF PREFERRED EMBODIMENTS

Examples are described below with reference to the appended drawings, and the drawings illustrate particular embodiments in which the present invention may be practiced. Directional terms mentioned in the present invention, such as upper, lower, front, rear, left, right, in, out, side, etc., only refer to directions in the accompanying drawings. Thus, the adoption of directional terms is used to describe and understand the present invention, but not to limit the present invention. In the drawings, units of similar structures are using the same numeral to represent.

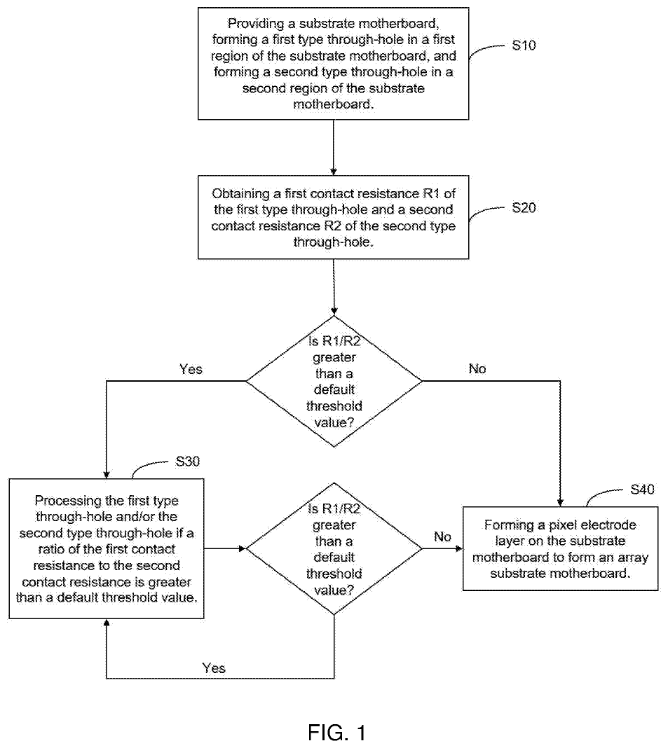

Please refer to FIG. 1, which is a flowchart of a manufacturing method of a display panel motherboard of the present invention.

The manufacturing method of the display panel motherboard includes a step:

S10, providing a substrate motherboard, forming a first type through-hole in a first region of the substrate motherboard, and forming a second type through-hole in a second region of the substrate motherboard.

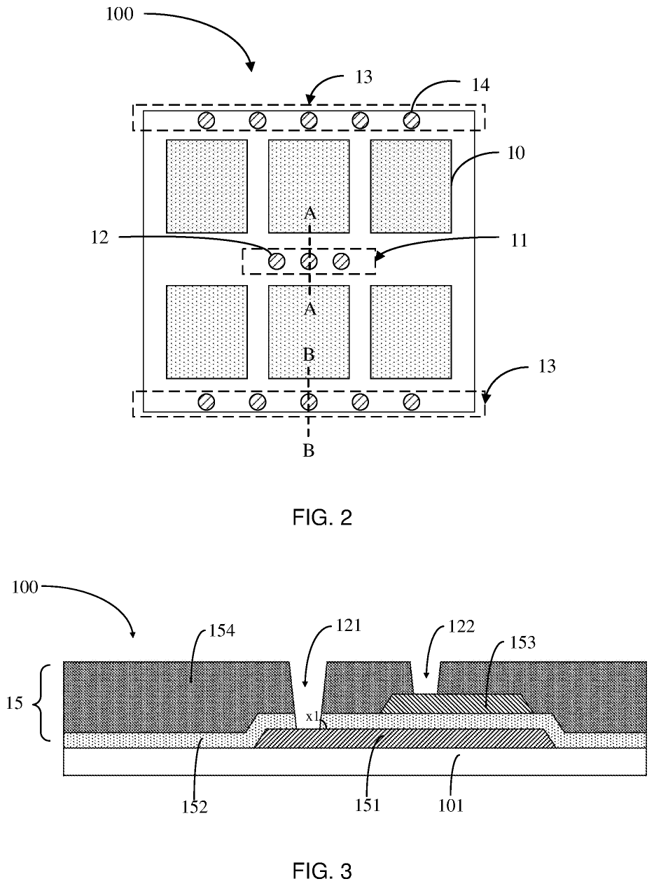

Please refer to FIG. 2, which is a plan schematic diagram of the substrate motherboard 100.

The substrate motherboard 100 includes a plurality of sub-regions 10, each of the plurality of sub-regions 10 corresponds to a display panel.

In this step, a plurality of first type through-holes 12 are formed in the first region 11 of the substrate motherboard 100 by an etching process, and a plurality of second type through-holes 14 are formed in the second region 13 of the substrate motherboard 100 by the etching process.

In this embodiment, the first type through-hole 12 and the second type through-hole 14 include different depth through-holes.

In this embodiment, the first region 11 is a central region of the substrate motherboard 100.

In this embodiment, the second region 13 is an edge region of the substrate motherboard 100.

Please refer to FIG. 3, which is a film structure diagram of a cross-sectional view A-A in FIG. 2.

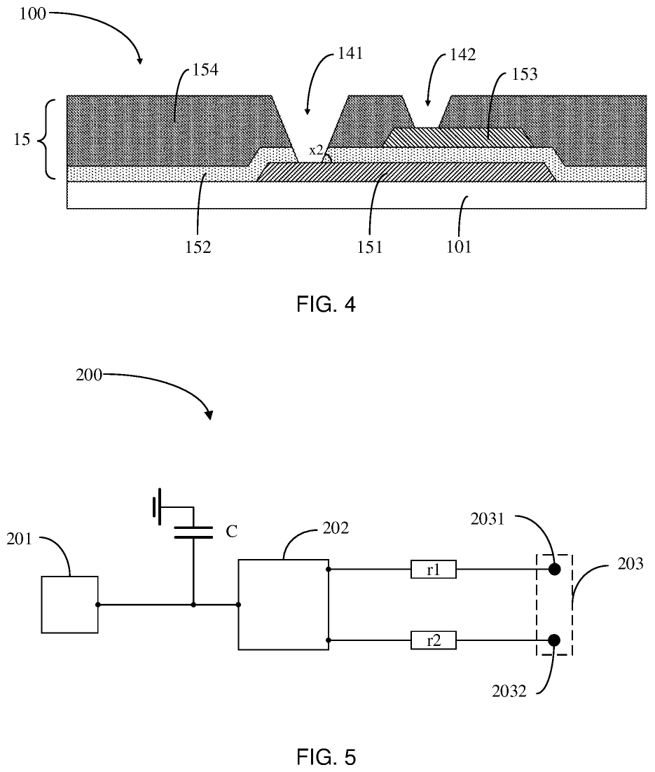

Please refer to FIG. 4, which is a film structure diagram of a cross-sectional view B-B in FIG. 2.

The substrate motherboard 100 includes a substrate 101 and a thin-film transistor layer 15 disposed on the substrate 101.

In this embodiment, if the display panel motherboard is a rigid panel, the substrate 101 can be one of a glass substrate, a quartz substrate, or a resin substrate, etc. If the display panel motherboard is a flexible panel, the substrate 101 can be made of a flexible material such as polyimide.

The thin-film transistor layer 15 can include an etch-stop type structure, a back-channel-etch type structure, a bottom-gate thin-film transistor type structure, or a top-gate thin-film transistor type structure, and is not particularly limited.

The present invention is described by taking a bottom-gate thin-film transistor type structure as an example. A bottom-gate thin-film transistor can include a buffer layer (not shown), an active layer (not shown), a gate insulating layer (not shown), a gate layer 151, an interlayer insulating layer 152, a source and drain layer 153, and a passivation layer 154, which are sequentially laminated.

Please refer to FIG. 3, the first type through-hole 12 includes a first through-hole 121 and a second through-hole 122.

The first through-hole 121 passes through the passivation layer 154 and the interlayer insulating layer 152 in the thin-film transistor layer 15, and exposes a portion of the gate layer 151 corresponding to the first through-hole 121. The second through-hole 122 passes through a portion of the passivation layer 154, and exposes a portion of the source and drain layer 153.

Please refer to FIG. 4, the second type through-hole 14 includes a third through-hole 141 and a fourth through-hole 142.

The third through-hole 141 passes through the passivation layer 154 and the interlayer insulating layer 152 in the thin-film transistor layer 15, and exposes a portion of the gate layer 151 corresponding to the third through-hole 141. The fourth through-hole 142 passes through the portion of the passivation layer 154, and exposes the portion of the source and drain layer 153.

Due to an accuracy problem of an etching process, when the first type through-hole 12 and the second type through-hole 14 are formed, a certain angle between a slope of these through-holes and a plan of the substrate 101 is formed. Different angles corresponding to the first type through-hole 12 and the second type through-hole 14 have different contact resistances.

S20, obtaining a first contact resistance of the first type through-hole and a second contact resistance of the second type through-hole.

The step S20 specifically includes as follows:

S201, obtaining a first angle between a slope of the first type through-hole and the substrate;

S202, obtaining a second angle between a slope of the second type through-hole and the substrate;

S203, obtaining the first contact resistance corresponding to the first angle according to the first angle; and

S204, obtaining the second contact resistance corresponding to the second angle according to the second angle.

In this step, the first angle is x1, the second angle is x2, the first contact resistance is R1, and the second contact resistance is R2.

In this embodiment, the first contact resistance R1 corresponding to the first angle x1 and the second contact resistance R2 corresponding to the second angle x2 can be obtained according to a functional relationship R=f(x).

Lastly, calculate a ratio of the first contact resistance to the second contact resistance, and compare it to a default threshold value.

In this embodiment, in order to ensure an accuracy of a measurement, contact resistances of the third through-hole 141 and the fourth through-hole 142 also need to be measured. The central region of the substrate motherboard 100 is referenced by the first through-hole 121 and the second through-hole 122. The edge region of the substrate motherboard 100 is referenced by the third through-hole 141 and the fourth through-hole 142.

Contact resistances of the first type through-hole 12 and the second type through-hole 14 can also be measured by resistance measuring devices, and the angles of these through-holes can be used as an auxiliary reference.

In this embodiment, the R is proportional to the x in the functional relationship R=f(x). The R is the contact resistance of the first type through-hole 12 or the second type through-hole 14, and the x is the angle between the slope of the first type through-hole 12 or the slope of the second type through-hole 14 and the substrate 101.

The larger the angle between these through-holes and the substrate 101 is, the greater the contact resistance of these through-holes is.

In this embodiment, the first angle x1 of the first type through-hole 12 in FIG. 3 is larger than the second angle x2 of the second type through-hole 14 in FIG. 4, which means the R1 is greater than the R2.

Please refer to FIG. 5, which is a simulation circuit diagram of a display panel of the present invention.

The simulation circuit 200 includes a clock signal input 201, a clock signal bus 202, a clock signal output 203, and a capacitor C.

The clock signal output 203 includes a first output 2031 and a second output 2032. A first resistor r1 is disposed between the clock signal bus 202 and the first output 2031. A second resistor r2 is disposed between the clock signal bus 202 and the second output 2032.

The present invention obtains a V_{gh} value in a thin-film transistor (TFT) by adjusting resistances of the first resistor r1 and the second resistor r2 and comparing it to a circuit without connecting the first resistor r1 and the second resistor r2 to obtain a rate of change of the V_{gh} value in the TFT.

In this embodiment, if a ratio of the resistance of the first resistor r1 to the resistance of the second resistor r2 is less than three, the rate of change of the V_{gh} value in the TFT is within an allowable range of a GOA circuit.

S30, processing the first type through-hole and/or the second type through-hole if a ratio of the first contact resistance to the second contact resistance is greater than a default threshold value.

In this step, for example, the default threshold value is three.

If the ratio of the first contact resistance to the second contact resistance is greater than the default threshold value, the first angle of the first type through-hole 12 is decreased by an etching process.

If the ratio of the first contact resistance to the second contact resistance is greater than the default threshold value, the second angle of the second type through-hole 14 is increased by an etching process.

If the ratio of the first contact resistance to the second contact resistance is greater than the default threshold value, the first angle of the first type through-hole 12 is decreased and the second angle of the second type through-hole 14 is increased by an etching process.

In the process, the first type through-hole 12 or the second type through-hole 14 are processed mainly by an etching process. Comparing to decreasing the angle of these through-holes, a process of increasing the angle of these through-holes is more complicated. Therefore, in this embodiment, the ratio of the first contact resistance to the second contact resistance is adjusted by decreasing the first angle of the first type through-hole 12.

In this embodiment, the first type through-hole 12 can also be adjusted by adjusting a film formation rate, a gas flow rate ratio, an ambient pressure, etc.

In this embodiment, the smaller the ratio of the first contact resistance to the second contact resistance is, the smaller the rate of change of the V_{gh} value in the TFT is, and the more stable the circuit of the display panel is.

S40, forming a pixel electrode layer on the substrate motherboard to form an array substrate motherboard if the ratio of the first contact resistance to the second contact resistance is less than the default threshold value.

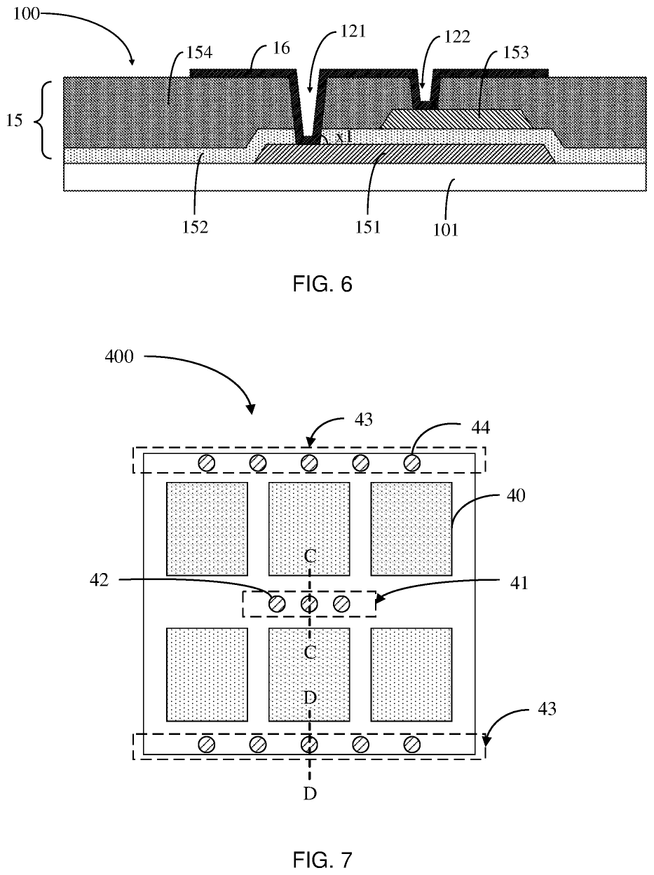

Please refer to FIG. 6, which is a film structure diagram of an array substrate motherboard of the present invention.

If the ratio of the first contact resistance to the second contact resistance is less than the default threshold value, a subsequent process of the substrate motherboard is performed.

The following description takes patterns of FIG. 3 or FIG. 4 as an example.

A pixel electrode layer 16 is coated on the passivation layer 154 of the substrate motherboard 100, patterned to form a predetermined pattern as shown in FIG. 6, and a preparation process of the array substrate motherboard 100 is completed.

In this embodiment, the pixel electrode layer 16 passes through the first through-hole 121 and the third through-hole 141 and electrically connects to the gate layer 151 in the thin-film transistor layer 15. The pixel electrode layer 16 passes through the second through-hole 122 and the fourth through-hole 142 and electrically connects to the source and drain layer 153 in the thin-film transistor layer 15.

In this embodiment, the pixel electrode layer 16 is a transparent metal material.

In this embodiment, the pixel electrode layer 16 can be indium tin oxide (ITO).

S50, aligning the array substrate motherboard with a color film substrate motherboard, and injecting liquid crystals between the array substrate motherboard and the color film substrate motherboard.

This step is mainly a cell process of the display panel motherboard.

If the display panel motherboard is an organic light-emitting diode (OLED) display panel motherboard, a light-emitting device layer and an encapsulation layer are formed on the array substrate motherboard.

A type of the display panel motherboard is not specifically limited in the present invention.

The display panel motherboard includes at least two display panels.

In the display panel motherboard of the present invention, the first type through-hole 12 is located on the at least two display panels near the central region of the substrate motherboard 100. The second type through-hole 14 is located on the at least two display panels near the edge region of the substrate motherboard 100.

In the display panel motherboard of the present invention, the first type through-hole 12 is located between two neighboring display panels near the central region of the substrate motherboard 100. The second type through-hole 14 is located on a non-display panel near the edge region of the substrate motherboard 100.

In the display panel motherboard of the present invention, the first type through-hole 12 is located on the at least two display panels near the central region of the substrate motherboard 100. The second type through-hole 14 is located on a non-display panel near the edge region of the substrate motherboard 100.

In the display panel motherboard of the present invention, the first type through-hole 12 is located between two neighboring display panels near the central region of the substrate motherboard 100. The second type through-hole 14 is located on the at least two display panels near the edge region of the substrate motherboard 100.

The present invention adjusts the angle between contact through-holes in the central region and the substrate and the angle between contact through-holes in the edge region and the substrate of the display panel motherboard to improve uniformity of resistances of the contact through-holes of the display panel circuit and improve quality of the display panel.

Please refer to FIG. 7, which is a plan schematic diagram of the display panel motherboard of the present invention.

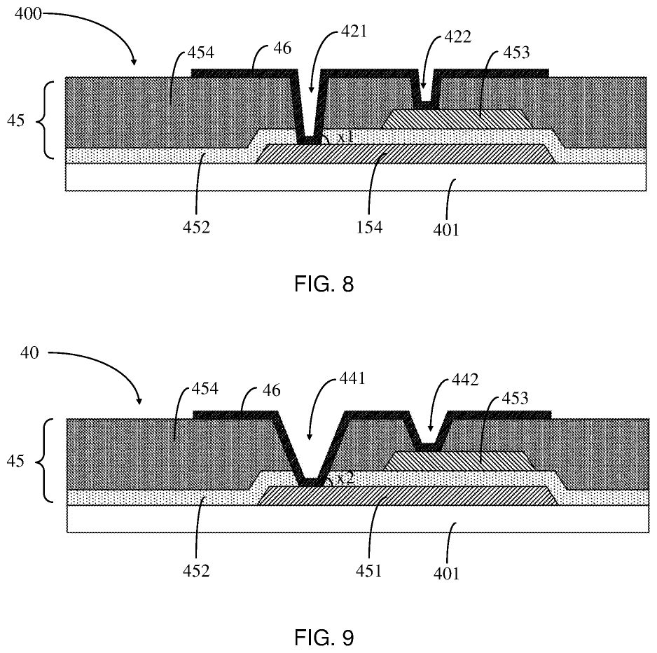

Please refer to FIG. 8, which is a film structure diagram of a cross-sectional view C-C in FIG. 7.

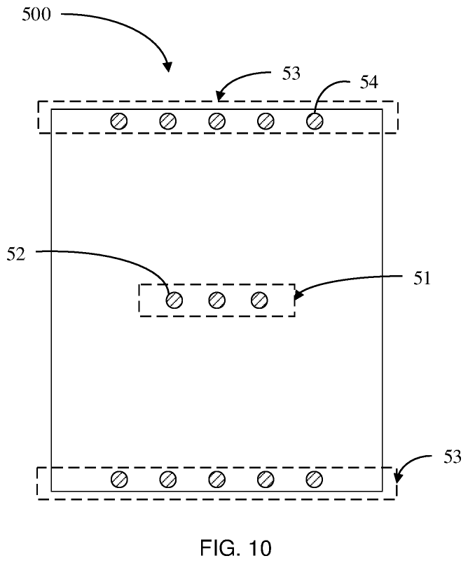

Please refer to FIG. 9, which is a film structure diagram of a cross-sectional view D-D in FIG. 7.

The display panel motherboard includes at least two display panels.

The display panel motherboard includes an array substrate motherboard 400, a color film substrate motherboard, and liquid crystals between the array substrate motherboard 400 and the color film substrate motherboard.

The array substrate motherboard 400 includes a substrate 401, a thin-film transistor layer 45 disposed on the substrate 401, and a pixel electrode layer 46 disposed on the thin-film transistor layer 45.

The array substrate motherboard 400 includes a plurality of sub-regions 40, and each of the plurality of sub-regions 40 corresponds to a display panel.

In this embodiment, if the display panel motherboard is a rigid panel, the substrate 401 can be one of a glass substrate, a quartz substrate, or a resin substrate, etc. If the display panel motherboard is a flexible panel, the substrate 401 can be made of a flexible material such as polyimide.

The thin-film transistor layer 45 can include an etch-stop type structure, a back-channel-etch type structure, a bottom-gate thin-film transistor type structure, or a top-gate thin-film transistor type structure, and is not particularly limited.

The present invention is described by taking a bottom-gate thin-film transistor type structure as an example. A bottom-gate thin-film transistor can include a buffer layer (not shown), an active layer (not shown), a gate insulating layer (not shown), a gate layer 451, an interlayer insulating layer 452, a source and drain layer 453, and a passivation layer 454, which are sequentially laminated.

The array substrate motherboard 400 further includes a first type through-hole 42 located in a first region 41 of the array substrate motherboard 400 and a second type through-hole 44 located in a second region 43 of the array substrate motherboard 400.

In this embodiment, the first type through-hole 42 and the second type through-hole 44 include different depth through-holes.

In this embodiment, the first region 41 is a central region of the array substrate motherboard 400.

In this embodiment, the second region 43 is an edge region of the array substrate motherboard 400.

Please refer to FIG. 8, the first type through-hole 42 includes a first through-hole 421 and a second through-hole 422.

The first through-hole 421 passes through the passivation layer 454 and the interlayer insulating layer 452 in the thin-film transistor layer 45, and exposes a portion of the gate layer 451 corresponding to the first through-hole 421. The second through-hole 422 passes through a portion of the passivation layer 454, and exposes a portion of the source and drain layer 453.

Please refer to FIG. 9, the second type through-hole 44 includes a third through-hole 441 and a fourth through-hole 442.

The third through-hole 441 passes through the passivation layer 454 and the interlayer insulating layer 452 in the thin-film transistor layer 45, and exposes a portion of the gate layer 451 corresponding to the third through-hole 441. The fourth through-hole 442 passes through the portion of the passivation layer 454, and exposes the portion of the source and drain layer 453.

Due to an accuracy problem of an etching process, when the first type through-hole 42 and the second type through-hole 44 are formed, a certain angle between a slope of these through-holes and a plan of the substrate 401 is formed. Different angles corresponding to the first type through-hole 42 and the second type through-hole 44 have different contact resistances.

In this embodiment, a first angle x1 between a slope of the first type through-hole 42 and the substrate 401 is an average angle between the first through-hole 421 and the second through-hole 422 and the substrate 401.

In this embodiment, a second angle x2 between a slope of the second type through-hole 44 and the substrate 401 is an average angle between the third through-hole 441 and the fourth through-hole 442 and the substrate 401.

In this embodiment, a first contact resistance R1 corresponding to the first angle x1 can be obtained according to a functional relationship R=f(x). A second contact resistance R2 corresponding to the second angle x2 can be obtained according to a functional relationship R=f(x).

Lastly, calculate a ratio of the first contact resistance to the second contact resistance, and compare it to a default threshold value.

In this embodiment, in order to ensure an accuracy of a measurement, contact resistances of the third through-hole 441 and the fourth through-hole 442 also need to be measured. The central region of the array substrate motherboard 400 is referenced by the first through-hole 421 and the second through-hole 422. The edge region of the array substrate motherboard 400 is referenced by the third through-hole 441 and the fourth through-hole 442.

Contact resistances of the first type through-hole 42 and the second type through-hole 44 can also be measured by resistance measuring devices, and the angles of these through-holes can be used as an auxiliary reference.

In this embodiment, the R is proportional to the x in the functional relationship R=f(x). The R is the contact resistance of the first type through-hole 42 or the second type through-hole 44, and the x is the angle between the slope of the first type through-hole 42 or the slope of the second type through-hole 44 and the substrate 401.

The larger the angle between these through-holes and the substrate 401 is, the greater the contact resistance of these through-holes is.

In this embodiment, the first angle x1 of the first type through-hole 42 in FIG. 8 is larger than the second angle x2 of the second type through-hole 44 in FIG. 9, which means the R1 is greater than the R2.

In this embodiment, the default threshold value is obtained according to the simulation circuit diagram in FIG. 5.

In this embodiment, for example, the default threshold value is less than three.

In this embodiment, the smaller the ratio of the first contact resistance to the second contact resistance is, the smaller the rate of change of the V_{gh} value in the TFT is, and the more stable the circuit of the display panel is.

In this embodiment, the pixel electrode layer 46 passes through the first through-hole 421 and the third through-hole 441 and electrically connects to the gate layer 451 in the thin-film transistor layer 45. The pixel electrode layer 46 passes through the second through-hole 422 and the fourth through-hole 442 and electrically connects to the source and drain layer 453 in the thin-film transistor layer 45.

In this embodiment, the pixel electrode layer 46 is a transparent metal material.

In this embodiment, the pixel electrode layer 46 can be indium tin oxide (ITO).

The display panel motherboard can also be an organic light-emitting diode (OLED) display panel motherboard.

A type of the display panel motherboard is not specifically limited in the present invention.

The display panel motherboard includes at least two display panels.

In the display panel motherboard of the present invention, the first type through-hole 42 is located on the at least two display panels near the central region of the array substrate motherboard 400. The second type through-hole 44 is located on the at least two display panels near the edge region of the array substrate motherboard 400.

In the display panel motherboard of the present invention, the first type through-hole 42 is located between two neighboring display panels near the central region of the array substrate motherboard 400. The second type through-hole 44 is located on a non-display panel near the edge region of the array substrate motherboard 400.

In the display panel motherboard of the present invention, the first type through-hole 42 is located on the at least two display panels near the central region of the array substrate motherboard 400. The second type through-hole 44 is located on a non-display panel near the edge region of the array substrate motherboard 400.

In the display panel motherboard of the present invention, the first type through-hole 42 is located between two neighboring display panels near the central region of the array substrate motherboard 400. The second type through-hole 44 is located on the at least two display panels near the edge region of the array substrate motherboard 400.

Please refer to FIG. 10, which is a plan schematic diagram of the display panel of the present invention.

The present invention provides a display panel 500, and the display panel 500 is cut from the above display panel motherboard.

The display panel 500 further includes a third type through-hole 52 located in a first region 51 of the display panel 500 and a fourth type through-hole 54 located in a second region 53 of the display panel 500.

A ratio of a first contact resistance of the third type through-hole 52 to a second contact resistance of the fourth type through-hole 54 is less than the default threshold value.

In this embodiment, the first region 51 is a central region of the display panel 500.

In this embodiment, the second region 53 is an edge region of the display panel 500.

In this embodiment, the third type through-hole 52 and the fourth type through-hole 54 are located on the display panel 500.

In order to ensure a stability of a circuit structure of each of the display panel, contact resistances of the third type through-hole 52 and the fourth type through-hole 54 on each of the display panel in the display panel motherboard need to be measured, and angles between the third type through-hole 52 and the fourth type through-hole 54 and the substrate on each of the display panel need to be adjusted.

Therefore, process difficulty and measurement difficulty of the third type through-hole 52 and the fourth type through-hole 54 are harder than process difficulty and measurement difficulty of the first type through-hole 42 and the second type through-hole 44 in FIG. 7.

Adjustment methods and principles of the third type through-hole 52 and the fourth type through-hole 54 are same as or similar to the embodiment in FIG. 7 and are not described herein again.

The present invention provides a display panel motherboard, a manufacturing method thereof, and a display panel. The manufacturing method of the display panel motherboard includes: forming a first type through-hole in a central region of a substrate motherboard, forming a second type through-hole in an edge region of the substrate motherboard, and comparing a ratio of a contact resistance of the first type through-hole to a contact resistance of the second type through-hole to a default threshold value for designing a display panel motherboard that meets requirements. The present invention adjusts an angle between contact through-holes in the central region and a substrate and an angle between contact through-holes in the edge region and the substrate of the display panel motherboard to improve uniformity of resistances of the contact through-holes of a display panel circuit and improve quality of the display panel.

Although the present invention has been disclosed above by the preferred embodiments, the preferred embodiments are not intended to limit the invention. One of ordinary skill in the art, without departing from the spirit and scope of the present invention, can make various modifications and variations of the present invention. Therefore, the scope of the claims to define the scope of equivalents.

What is claimed is:

1. A manufacturing method of a display panel motherboard, comprising at least two display panels;
wherein the manufacturing method of the display panel motherboard comprises steps of:
providing a substrate motherboard, forming a first type through-hole in a first region of the substrate motherboard, and forming a second type through-hole in a second region of the substrate motherboard;
obtaining a first contact resistance of the first type through-hole and a second contact resistance of the second type through-hole;
processing the first type through-hole and/or the second type through-hole if a ratio of the first contact resistance to the second contact resistance is greater than a default threshold value; and
forming a pixel electrode layer on the substrate motherboard to form an array substrate motherboard if the ratio of the first contact resistance to the second contact resistance is less than the default threshold value.

2. The manufacturing method of the display panel motherboard according to claim 1, wherein the substrate motherboard comprises a substrate and a thin-film transistor layer disposed on the substrate; and
the step of obtaining the first contact resistance of the first type through-hole and the second contact resistance of the second type through-hole comprises steps of:
obtaining a first angle between a slope of the first type through-hole and the substrate;
obtaining a second angle between a slope of the second type through-hole and the substrate;
obtaining the first contact resistance corresponding to the first angle according to the first angle; and
obtaining the second contact resistance corresponding to the second angle according to the second angle.

3. The manufacturing method of the display panel motherboard according to claim 2, wherein if the ratio of the first contact resistance to the second contact resistance is greater than the default threshold value, the first angle of the first type through-hole is decreased by an etching process.

4. The manufacturing method of the display panel motherboard according to claim 2, wherein if the ratio of the first contact resistance to the second contact resistance is greater than the default threshold value, the second angle of the second type through-hole is increased by an etching process.

5. The manufacturing method of the display panel motherboard according to claim 2, wherein if the ratio of the first contact resistance to the second contact resistance is greater than the default threshold value, the first angle of the first type through-hole is decreased and the second angle of the second type through-hole is increased by an etching process.

6. The manufacturing method of the display panel motherboard according to claim 1, wherein the first region is a central region of the substrate motherboard; and
the second region is an edge region of the substrate motherboard.

7. The manufacturing method of the display panel motherboard according to claim 6, wherein the first type through-hole is located on the at least two display panels near the central region of the substrate motherboard; and
the second type through-hole is located on the at least two display panels near the edge region of the substrate motherboard.

8. The manufacturing method of the display panel motherboard according to claim 6, wherein the first type through-hole is located between two neighboring display panels near the central region of the substrate motherboard; and
the second type through-hole is located on a non-display panel near the edge region of the substrate motherboard.

9. The manufacturing method of the display panel motherboard according to claim 6, wherein the first type through-hole is located on the at least two display panels near the central region of the substrate motherboard; and
the second type through-hole is located on a non-display panel near the edge region of the substrate motherboard.

10. The manufacturing method of the display panel motherboard according to claim 6, wherein the first type through-hole is located between two neighboring display panels near the central region of the substrate motherboard; and
the second type through-hole is located on the at least two display panels near the edge region of the substrate motherboard.

11. The manufacturing method of the display panel motherboard according to claim 1, wherein the manufacturing method of the display panel motherboard further comprises steps of:
aligning the array substrate motherboard with a color film substrate motherboard, and injecting liquid crystals between the array substrate motherboard and the color film substrate motherboard.

12. A display panel motherboard, comprising at least two display panels and an array substrate motherboard;
wherein the array substrate motherboard comprises a first type through-hole located in a first region of the array substrate motherboard and a second type through-hole located in a second region of the array substrate motherboard; and
a ratio of a first contact resistance of the first type through-hole to a second contact resistance of the second type through-hole is less than a default threshold value.

13. The display panel motherboard according to claim 12, wherein the first region is a central region of the array substrate motherboard; and
the second region is an edge region of the array substrate motherboard.

14. The display panel motherboard according to claim 13, wherein the first type through-hole is located on the at least two display panels near the central region of the array substrate motherboard; and
the second type through-hole is located on the at least two display panels near the edge region of the array substrate motherboard.

15. The display panel motherboard according to claim 13, wherein the first type through-hole is located between two neighboring display panels near the central region of the array substrate motherboard; and
the second type through-hole is located on a non-display panel near the edge region of the array substrate motherboard.

16. The display panel motherboard according to claim 13, wherein the first type through-hole is located on the at least two display panels near the central region of the array substrate motherboard; and
the second type through-hole is located on a non-display panel near the edge region of the array substrate motherboard.

17. The display panel motherboard according to claim 13, wherein the first type through-hole is located between two neighboring display panels near the central region of the array substrate motherboard; and
the second type through-hole is located on the at least two display panels near the edge region of the array substrate motherboard.

18. The display panel motherboard according to claim 13, wherein the first type through-hole comprises a first through-hole and a second through-hole;
the first through-hole passes through a passivation layer and an interlayer insulating layer in the array substrate motherboard, and the second through-hole passes through a portion of the passivation layer;
the second type through-hole comprises a third through-hole and a fourth through-hole; and
the third through-hole passes through the passivation layer and the interlayer insulating layer in the array substrate motherboard, and the fourth through-hole passes through the portion of the passivation layer.

19. A display panel cut from the display panel motherboard according to claim 12, comprising a third type through-hole located in a first region of the display panel and a fourth type through-hole located in a second region of the display panel;
wherein a ratio of a first contact resistance of the third type through-hole to a second contact resistance of the fourth type through-hole is less than the default threshold value.

20. The display panel according to claim 19, wherein the first region is a central region of the display panel; and
the second region is an edge region of the display panel.
